(19) United States
(12) Patent Application Publication
(10) Pub. No.: US 2012/0156625 A1
(43) Pub. Date: Jun. 21, 2012

(54) NANO-FABRICATION METHOD

(75) Inventor: Chun-Cheng Chang, Nantou County (TW)

(73) Assignee: RITEK CORPORATION, Hsinchu (TW)

(21) Appl. No.: 12/975,081

(22) Filed: Dec. 21, 2010

(51) Int. Cl. G03F 7/20; B82Y 40/00

(52) U.S. Cl. 430/325; 977/840

(57) ABSTRACT

Disclosed herein is a nano-fabrication method, which includes the step of: (a) forming an inorganic resist layer on a substrate; (b) forming an organic photoresist layer on the inorganic resist layer; (c) irradiating both the organic photoresist layer and the inorganic resist layer with a laser beam to form a first exposed region of the inorganic resist layer and a second exposed region of the organic photoresist layer; (d) removing the inorganic resist layer of the first exposed region and the organic photoresist layer of the second exposed region to form a patterned inorganic resist layer and a patterned organic photoresist layer; and (e) removing the patterned organic photoresist layer from the patterned inorganic resist layer.

### BACKGROUND

1. Field of Invention

The present invention relates to a nano-fabrication method. More particularly, the present invention relates to a nano-fabrication method combining an inorganic resist layer with an organic photoresist layer.

2. Description of Related Art

By rapid progresses of 3C products and technologies, semiconductors and information recording media require smaller structures to improve the operation speed and/or the recording density. Taking optical disc storage as an example, conventional read-only DVDs (DVD-ROMs) has a spiral pit string with a pit length of 0.4 μm and a track pitch of 0.74 μm, but the Blue-ray Disc Recordable (BD-R) requires a pit length of 0.17 μm and a track pitch of 0.32 μm. Moreover, Blue-ray disc re-writable (BD-Re) requires not only a track pitch of 0.32 μm, but also a track depth of only 20 nm.

One solution to this issue is by using a short-wavelength laser with a wavelength of 197 nm. Unfortunately, the exposure system of the short-wavelength laser is extremely expensive because the optical elements must be made of specific materials, and thus rendering this approach cost in-effective.

To achieve the high precision pattern, using inorganic resist material is an approach to achieve this requirement. Inorganic resist material refers to a material performs a phase transition while being irradiated, and therefore may be patterned by photolithography. Inorganic resists also provide a clear pattern at the boundary between the exposed and unexposed areas compared to organic resists.

However, the inorganic resists have a problem in that it requires a certain thickness to passes the capability of the photolithography. Particularly, if the thickness is less than about 70 nm, it is difficult to obtain a uniform and precise pattern by using typical blue laser, and therefore is difficult to be applied in the manufacturing process of BD-Re.

In view of the above, there exists in the art a new method that would resolve the above mentioned problem.

### SUMMARY

A nano-fabrication method is provided. The nano-fabrication method comprises the following process. An inorganic resist layer is formed on a substrate. The inorganic resist layer is capable of performing a phase transition while being irradiated by a laser beam. An organic photoresist layer is formed on the inorganic resist layer. And then, both the organic photoresist layer and the inorganic resist layer are irradiated with the laser beam so as to form a first exposed region of the inorganic resist layer and a second exposed region of the organic photoresist layer. The first exposed region of the inorganic resist layer performs the phase transition. Subsequently, the first exposed region of the inorganic resist layer and the second exposed region of the organic photoresist layer are removed; and thus forming a patterned inorganic resist layer and a patterned organic photoresist layer. The patterned organic photoresist layer is then removed from the patterned inorganic resist layer.

According to one embodiment of the present disclosure, the inorganic resist layer has a thickness of less than 75 nm.

According to another embodiment of the present disclosure, the substrate may comprise a light absorption layer disposed thereon, and the inorganic resist layer is formed on and in contact with the light absorption layer. The light absorption layer may comprise at least one material selected from the group consisting of Si, Ge, GaAs, Bi, Ga, In, Sn, Sb, Te, BiTe, BiIn, GaSb, GaP, InP, InSb, InTe, C, SiC, V₂O₅, Cr₂O₃, Mn₃O₄, Fe₂O₃, Co₃O₄, CuO, AlN, GaN, GeSbTe, InSbTe, BiSbTe, GaSbTe and AgInSbTe. In some examples, the light absorption layer has a thickness of about 10 nm to about 50 nm.

In one embodiment, the inorganic resist layer comprises an inorganic resist material that converts into a crystal phase from an amorphous phase while being irradiated.

In one embodiment, the inorganic resist layer comprises an incomplete oxide of a phase-change material, wherein the incomplete oxide has a general formula of A₍₁₋ₓ₎Oₓ, wherein A represents the phase-change material, and x is a number of about 0.05 to about 0.65. In one example, the phase-change material comprises Ge—Sb—Te, Ge—Sb—Sn, or In—Ge—Sb—Te alloy. For instance, the inorganic resist layer may comprise a material having a formula of GeₓSb_{y}Sn_{z}O_{(1-x-y-z)}, wherein x is a number of about 0.1 to about 0.3, y is a number of about 0.2 to about 0.5, and z is a number of about 0.2 to about 0.6, with a proviso of (1-x-y-z) greater than 0.05.

In another embodiment, the inorganic resist comprises an incompletely oxidized transition metal alloy having an oxygen content lower than the stoichiometric oxygen content of the completely oxidized transition metal alloy, wherein the transition metal is selected from the group consisting of Ti, V, Cr, Mn, Fe, Nb, Cu, Ni, Co, Mo, Ta, W, Zr, Ru, and Ag.

In still another embodiment, the inorganic resist layer comprises tellurium oxide having a formula of TeOₓ, wherein x is a number of about 0.3 to about 1.7.

In some embodiments, the inorganic resist layer comprises an incompletely oxidized metal, wherein the metal is an element of 14^{th} group or 15^{th} group, and the oxygen content in the incompletely oxidized metal is in the range of 75% to 95% of the stoichiometrical oxygen content of the completely oxidized metal.

According to the embodiments of the present disclosure, the substrate may comprise a glass substrate, a silicon substrate, a single crystal alumina (Al₂O₃) substrate, a quartz substrate or a metal substrate.

According to the embodiments of the present disclosure, the organic photoresist layer comprises a novolac-type photoresist or a chemically amplified photoresist. In one example, the organic photoresist layer has a thickness of about 20 nm to about 60 nm.

According to the embodiments of the present disclosure, the laser beam has a wavelength of about 250 nm to about 500 nm.

According to the embodiments of the present disclosure, the inorganic resist layer of the first exposed region and the organic photoresist layer of the second exposed region are removed by applying an alkali solution.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a flow chart of a nano-fabrication method according to one embodiment of the present disclosure; and

FIG. 2A to FIG. 2E are cross-sectional views schematically illustrating process steps described in FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The present disclosure provides a nano-fabrication method for fabricating a nano-structure on a substrate. The nano-fabrication method comprises the step of: (a) forming an inorganic resist layer on a substrate, wherein the inorganic resist layer is capable of performing a phase transition while being irradiated by a laser beam; (b) forming an organic photoresist layer on and in contact with the inorganic resist layer; (c) irradiating both the organic photoresist layer and the inorganic resist layer with the laser beam to form a first exposed region of the inorganic resist layer and a second exposed region of the organic photoresist layer, such that the first exposed region of the inorganic resist layer performs the phase transition, wherein the first exposed region overlaps the second exposed region; (d) removing the inorganic resist layer of the first exposed region and the organic photoresist layer of the second exposed region to form a patterned inorganic resist layer and a patterned organic photoresist layer; and (e) removing the patterned organic photoresist layer from the patterned inorganic resist layer.

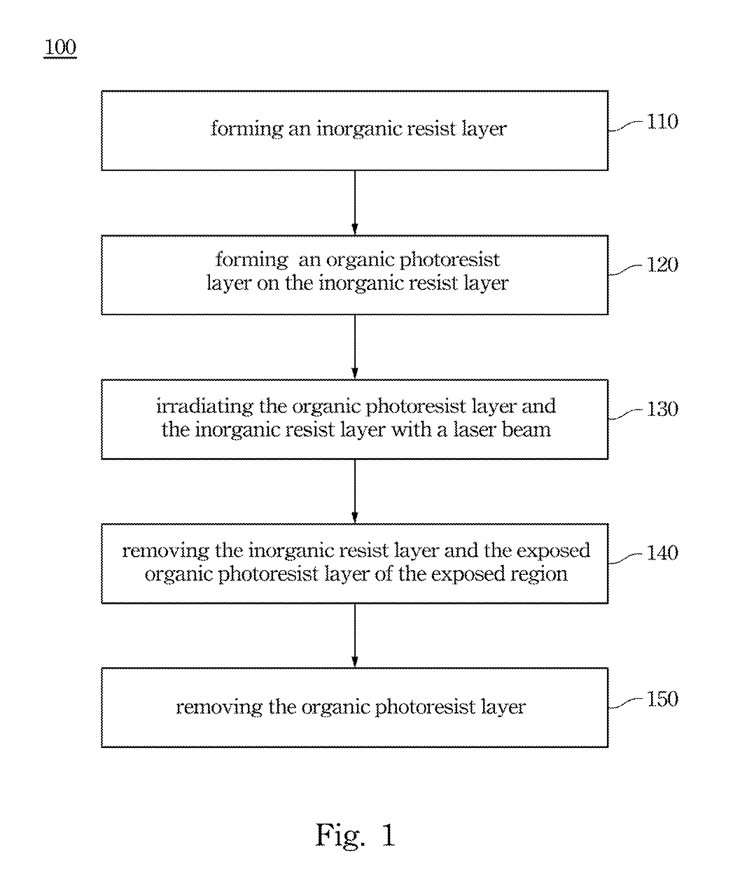

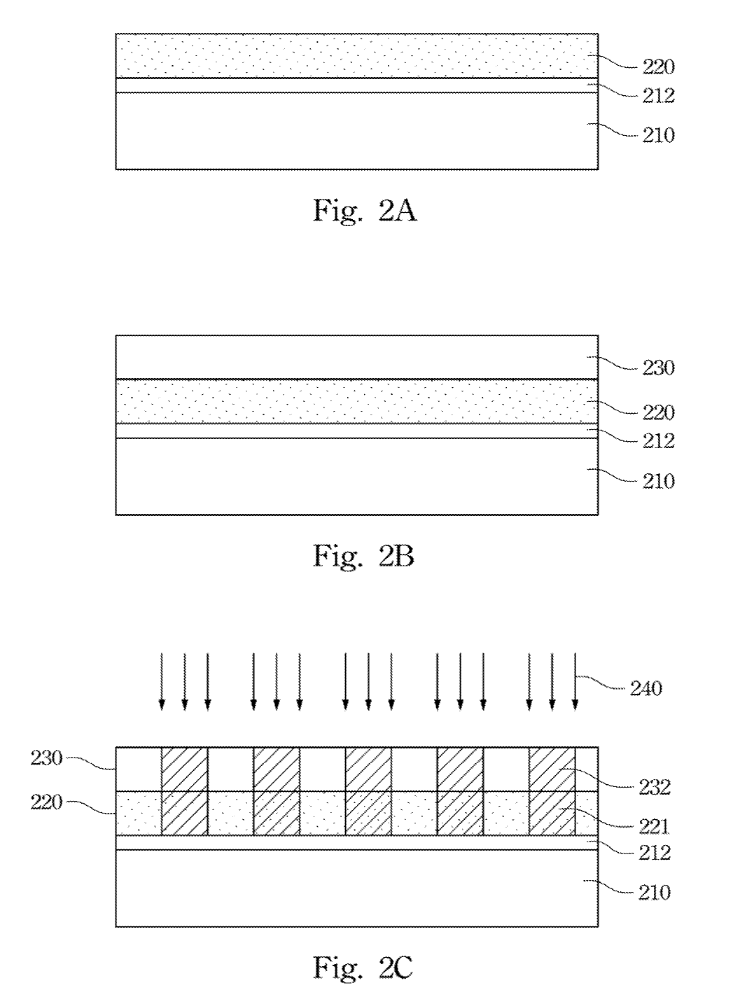

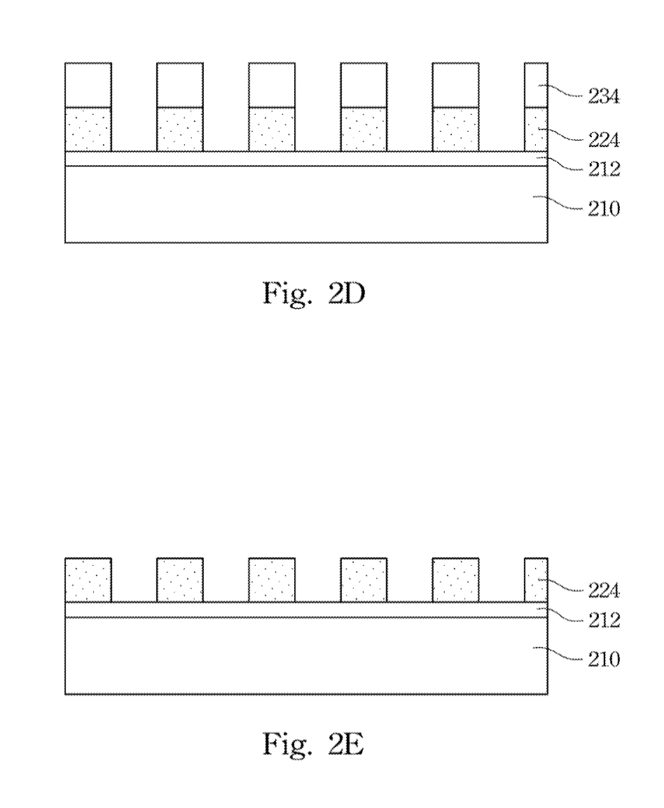

FIG. 1 is a flow chart of a nano-fabrication method 100 according to one embodiment of the present disclosure. FIG. 2A to FIG. 2E are cross-sectional views schematically illustrating process steps described in FIG. 1.

In step 110, an inorganic resist layer 220 is formed on a substrate 210, as depicted in FIG. 2A. The inorganic resist layer is capable of performing a phase transition while being irradiated by a laser beam or being heated. For example, the inorganic resist layer may be converted into a crystal phase from an amorphous phase while being irradiated by a laser beam. In one embodiment, the thickness of the inorganic resist layer 220 may be about 20 nm to about 150 nm, specifically less than 75 nm, more specifically about 20 nm to about 50 nm.

In one embodiment, the inorganic resist layer 220 may comprise an incomplete oxide of a phase-change material. The incomplete oxide has a general formula of A₍₁₋ₓ₎Oₓ, in which A represents the phase-change material, and x is a number of about 0.05 to about 0.65. Specifically, the phase-change material may be a Ge—Sb—Te alloy, a Ge—Sb—Sn alloy, or an In—Ge—Sb—Te alloy. In one example, the inorganic resist layer may comprise a material having a formula of GeₓSb_{y}Sn_{z}O_{(1-x-y-z)}, wherein x is a number of about 0.1 to about 0.3, y is a number of about 0.2 to about 0.5, and z is a number of about 0.2 to about 0.6, with a proviso of (1-x-y-z) greater than about 0.05.

In another embodiment, the inorganic resist layer 220 may comprise an incompletely oxidized transition metal alloy, which has an oxygen content lower than the stoichiometric oxygen content of the completely oxidized transition metal alloy. In this embodiment, the transition metal is selected from the group consisting of Ti, V, Cr, Mn, Fe, Nb, Cu, Ni, Co, Mo, Ta, W, Zr, Ru, and Ag.

In still another embodiment, the inorganic resist layer 220 may comprise tellurium oxide having a formula of TeOₓ, wherein x is a number of about 0.3 to about 1.7.

In some embodiments, the inorganic resist layer 220 may comprise an incompletely oxidized metal. The metal in the incompletely oxidized metal is an element of 14^{th} group or 15^{th} group. The oxygen content in the incompletely oxidized metal is in the range of 75% to 95% of the stoichiometrical oxygen content of the completely oxidized metal.

The material of the substrate 210 is not limited, so long as it has a sufficient heat-resistant to endure the conditions of the following processes. For example, the substrate 210 may be a glass substrate, silicon substrate, single crystal alumina (Al₂O₃) substrate, quartz substrate or metal substrate.

In one embodiment, the substrate 210 comprises a light absorption layer 212 disposed thereon, and the inorganic resist layer 220 is formed on and in contact with the light absorption layer 212. The light absorption layer may convert light into heat, and therefore may facilitate the phase transition of the inorganic resist layer. In examples, the material of the light absorption layer may be Si, Ge, GaAs, Bi, Ga, In, Sn, Sb, Te, BiTe, BiIn, GaSb, GaP, InP, InSb, InTe, C, SiC, V₂O₅, Cr₂O₃, Mn₃O₄, Fe₂O₃, Co₃O₄, CuO, AlN, GaN, GeSbTe, InSbTe, BiSbTe, GaSbTe, AgInSbTe, or a combination thereof. In this embodiment, the thickness of the light absorption layer may be in the range of about 10 nm to about 50 nm, specifically about 20 nm. In some examples, when the thickness of the light absorption layer 212 is greater than a certain value, for example about 50 nm, the resolution of the inorganic resist layer decreases. On the other hand, when the thickness of the light absorption layer 212 is less than certain value, for example 10 nm, it may not provide the function to facilitate the phase transition of the inorganic resist layer.

In step 120, an organic photoresist layer 230 is formed on the inorganic resist layer 220, as depicted in FIG. 2B. The photoresist layer 230 is in contact with the inorganic resist layer 220. The organic photoresist layer 230 may be a positive type photoresist. In one example, the organic photoresist layer 230 may be a novolac-type photoresist or a chemically amplified photoresist. In some embodiments, the thickness of the organic photoresist layer 230 is about 10 nm to about 60 nm, specifically about 20 nm to about 50 nm. In some examples, when the thickness of the organic photoresist layer 230 is greater than a certain value, for example about 60 nm, it would shield the inorganic resist layer 220 form the laser beam, and is unfavorable to the following process. In contrast, when the thickness of the organic photoresist layer 230 is less than certain value, for example about 10 nm, it may not provide the function that it should possess.

In step 130, both the organic photoresist layer 230 and the inorganic resist layer 220 are irradiated by a laser beam 240, as depicted in FIG. 2C. The laser beam 240 may penetrate both the organic photoresist layer 230 and the inorganic resist layer 220, and thus forming a first exposed region 221 of the inorganic resist layer 220 and a second exposed region 232 of the organic photoresist layer 230. Since the first and second exposed regions 221, 232 are irradiated by the same laser beam, the first exposed region 221 is overlapped by the second exposed region 232. In one embodiment, the wavelength of the laser beam 240 is about 250 nm to about 500 nm, specifically about 380 nm to about 450 nm.

The first exposed region 221 of the inorganic resist layer 220 performs a phase transition due to the irradiation of the laser beam 240. Therefore, the first exposed region 221 has a different phase from the unexposed region of the inorganic resist layer 220. Particularly, the first exposed region 221 has a crystal phase whereas the unexposed region of the inorganic resist layer 220 has an amorphous phase. The first exposed region 221 of the inorganic resist layer 220 becomes soluble to certain chemicals such as alkali solution.

In the case where the organic photoresist layer 230 is a positive type photoresist, the second exposed region 232 of the organic photoresist layer 230 becomes soluble to the photoresist developer such as alkali solution, which is known in the art.

In step 140, both the inorganic resist layer 220 of the first exposed region 221 and the organic photoresist layer 230 of the second exposed region 232 are removed, and thus forming a a patterned organic photoresist layer 234 and patterned inorganic resist layer 224 on the substrate 210, as depicted in FIG. 2D. In this step, the removal of the material in the first and second exposed regions 221, 232 may be accomplished by applying an alkali solution such as potassium hydroxide (KOH) solution and sodium hydroxide (NaOH) solution.

In step 150, the patterned organic photoresist layer 234 are removed from the patterned inorganic resist layer 224, as depicted in FIG. 2E. In this step, the patterned organic photoresist layer 234 may be removed by applying a photoresist stripper solution to peel off the photoresist. Alternatively, it may be removed by applying a solvent that may dissolve the unexposed organic photoresist layer 234. For example, solvents such as acetone may be employed to dissolve the remained organic photoresist layer 234. In one example, the patterned inorganic resist layer 224 remained in the substrate 210 has a width of about 170 nm and a thickness of about 20 nm.

### EXAMPLES

The following Examples are provided to illustrate certain aspects of the present invention and to aid those of skill in the art in practicing this invention. These Examples are in no way to be considered to limit the scope of the invention in any manner.

### Comparative Example 1

### Patterning an Inorganic Resist Layer About 20 nm in Thickness Without a Light Absorption Layer and a Organic Photoresist Layer

An inorganic resist layer about 20 nm in thickness was deposited on a glass substrate using a Ge_{13.5}Sb₄₀Sb_{46.5} target in an argon-oxygen mixed atmosphere (Ar/O₂=5/1) by sputtering. The sputtering process was carried out with a power of 200 W, and the pressure in the sputtering chamber was 0.8 Pa.

The substrate coated with the inorganic resist layer was disposed on a turntable of an exposure apparatus capable of providing a focused laser beam having a wavelength of 405 nm. The exposure was carried out in a way that the turntable was rotated continuously while the focused laser beam was moved in a radial direction, wherein the linear velocity of the rotation during the exposure was 4.0 m/s, and irradiation power was 6.0 mW.

After the exposure, the inorganic resist layer was developed by a wet process with KOH solution with a concentration of 0.05 M. The developing time period was 60 sec. The developed substrate was sufficiently washed with pure water and then was dried by, for example, an air blast to finish the process. Subsequently, an atomic force microscopy (AFM) was employed to analyze the inorganic resist layer pattern.

In this comparative example, a desired pattern was not obtained because the desired phase transition caused by the exposure was not occurred due to the extremely thin thickness of the inorganic resist layer.

### Comparative Example 2

### Patterning an Inorganic Resist Layer About 20 nm in Thickness with a Light Absorption Layer of 50 nm

A 50 nm silicon layer, as a light absorption layer, was deposited on a glass substrate in an argon (Ar) atmosphere by sputtering. During the silicon sputtering, a DC source of 350 W was used, the pressure in the process chamber was 0.5 Pa, and the Ar flow rate was 30 sccm. Next, a 20 nm layer of the inorganic resist layer was deposited on the silicon layer, and followed by the exposure and developing in accordance with the procedure described in COMPARATIVE EXAMPLE 1.

In this comparative example, an inorganic resist pattern was obtained, but the profile of the pattern was very rough and was poor in uniformity. Accordingly, it was difficult to be practiced.

### Comparative Example 3

### Patterning an Inorganic Resist Layer About 20 nm in Thickness with a Light Absorption Layer of 20 nm

In this embodiment, the inorganic resist pattern was prepared by the same method as described in COMPARATIVE. EXAMPLE 1, except that the silicon layer was 20 nm in thickness.

In this comparative example, a clear pattern of the inorganic resist layer was obtained. However, the top surface of the inorganic resist layer exhibited an unsatisfied roughness.

### Comparative Example 4

### Patterning an Inorganic Resist Layer About 30 nm in Thickness with a Light Absorption Layer of 20 nm

A 20 nm silicon layer, as a light absorption layer, was deposited on a glass substrate by the same method as described in COMPARATIVE EXAMPLE 3. Next, a 30 nm layer of the inorganic resist was deposited on the silicon layer using a Ge_{14.5}Sb₄₀Sb_{45.5} target in an argon-oxygen mixed atmosphere (Ar/O₂=5/1) by sputtering. The following exposure and developing processes were similar to these described above. In this comparative example, the thickness of the inorganic resist layer was increased to 30 nm, and the germanium content of the target was increased to 14.5%.

In this comparative example, the obtained surface profile of the inorganic resist layer pattern was similar to COMPARATIVE EXAMPLE 3. An unsatisfied roughness still presented on the top surface of the inorganic resist layer even though the thickness and the composition of the inorganic resist layer were modified.

### Example

### Patterning an Inorganic Resist Layer by Combining an Organic Photoresist

A 20 nm silicon layer, as a light absorption layer, was deposited on a glass substrate by sputtering in an argon (Ar) atmosphere at a pressure of 0.5 Pa. During the silicon sputtering, a DC source of 350 W was used and the Ar flow rate was 30 sccm. Next, an inorganic resist layer about 20 nm in thickness was deposited on the silicon layer, by sputtering, using a Ge_{13.5}Sb₄₀Sb_{46.5} target in an argon-oxygen mixed atmosphere (Ar/O₂=5/1) at a pressure of 0.8 Pa. Subsequently, a novolac-type photoresist was coated on the inorganic resist layer by spin costing, and followed by a baking process at a temperature of 130° C. for 900 seconds. An organic photoresist layer about 25 nm in thickness was formed on the inorganic resist layer.

The substrate coated with the organic photoresist layer was exposed to a laser beam with a wavelength of 405 nm. The exposure was carried out with an irradiation power of 3.2 mW and a linear velocity of 4.0 m/s by the method described in COMPARATIVE EXAMPLE 1. The laser beam penetrated both the organic photoresist layer and the inorganic resist layer.

After the exposure, a developing process was performed by KOH solution with a concentration of 0.05 M. The developing time period in this example was 40 sec. Both the exposed organic photoresist layer and the exposed inorganic resist layer were dissolved in the KOH solution, whereas the unexposed portions were remained on the substrate. Therefore, both of the organic photoresist layer and the inorganic resist layer were simultaneously patterned. The unexposed organic photoresist was removed by using acetone and an inorganic resist layer pattern was obtained.

In this example, a clear pattern of the inorganic resist layer was obtained and the inorganic resist layer exhibited a smooth top surface.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A nano-fabrication method, comprising:
(a) forming an inorganic resist layer on a substrate, wherein the inorganic resist layer is capable of performing a phase transition while being irradiated by a laser beam;
(b) forming an organic photoresist layer on and in contact with the inorganic resist layer;
(c) irradiating both the organic photoresist layer and the inorganic resist layer with the laser beam to form a first exposed region of the inorganic resist layer and a second exposed region of the organic photoresist layer, such that the first exposed region of the inorganic resist layer performs the phase transition, wherein the first exposed region overlaps the second exposed region;
(d) removing the first exposed region of the inorganic resist layer and the second exposed region of the organic photoresist layer to form a patterned inorganic resist layer and a patterned organic photoresist layer having a nano-structure; and
(e) removing the patterned organic photoresist layer from the patterned inorganic resist layer.

2. The nano-fabrication method of claim 1, wherein the inorganic resist layer of the step (a) has a thickness of less than about 75 nm.

3. The nano-fabrication method of claim 1, wherein the substrate of the step (a) comprises a light absorption layer disposed thereon, and the inorganic resist layer is formed on and in contact with the light absorption layer.

4. The nano-fabrication method of claim 3, wherein the light absorption layer comprises at least one material selected from the group consisting of Si, Ge, GaAs, Bi, Ga, In, Sn, Sb, Te, BiTe, BiIn, GaSb, GaP, InP, InSb, InTe, C, SiC, V₂O₅, Cr₂O₃, Mn₃O₄, Fe₂O₃, Co₃O₄, CuO, AlN, GaN, GeSbTe, InSbTe, BiSbTe, GaSbTe and AgInSbTe.

5. The nano-fabrication method of claim 3, wherein the light absorption layer has a thickness of about 10 nm to about 50 nm.

6. The nano-fabrication method of claim 1, wherein the inorganic resist layer of the step (a) comprises an inorganic resist material that converts into a crystal phase from an amorphous phase while being irradiated.

7. The nano-fabrication method of claim 1, wherein the inorganic resist layer of the step (a) comprises an incomplete oxide of a phase-change material, wherein the incomplete oxide has a general formula of A₍₁₋ₓ₎Oₓ, wherein A represents the phase-change material, and x is a number of about 0.05 to about 0.65.

8. The nano-fabrication method of claim 7, wherein the phase-change material comprises Ge—Sb—Te, Ge—Sb—Sn, or In—Ge—Sb—Te alloy.

9. The nano-fabrication method of claim 1, wherein the inorganic resist layer of the step (a) comprises a material having a formula of GeₓSb_{y}Sn_{z}O_{(1-x-y-z)}, wherein x is a number of about 0.1 to about 0.3, y is a number of about 0.2 to about 0.5, and z is a number of about 0.2 to about 0.6, with a proviso of (1-x-y-z) greater than 0.05.

10. The nano-fabrication method of claim 1, wherein the inorganic resist layer of the step (a) comprises an incompletely oxidized transition metal alloy having an oxygen content lower than the stoichiometric oxygen content of the completely oxidized transition metal alloy, wherein the transition metal is selected from the group consisting of Ti, V, Cr, Mn, Fe, Nb, Cu, Ni, Co, Mo, Ta, W, Zr, Ru, and Ag.

11. The nano-fabrication method of claim 1, wherein the inorganic resist layer of the step (a) comprises tellurium oxide having a formula of TeOₓ, wherein x is a number of about 0.3 to about 1.7.

12. The nano-fabrication method of claim 1, wherein the inorganic resist layer of the step (a) comprises an incompletely oxidized metal, wherein the metal is an element of 14^{th} group or 15^{th} group, and the oxygen content in the incompletely oxidized metal is in the range of 75% to 95% of the stoichiometrical oxygen content of the completely oxidized metal.

13. The nano-fabrication method of claim 1, wherein the substrate of the step (a) comprises a glass substrate, a silicon substrate, a single crystal alumina (Al₂O₃) substrate, a quartz substrate or a metal substrate.

14. The nano-fabrication method of claim 1, wherein the organic photoresist layer of the step (b) comprises a novolac-type photoresist or a chemically amplified photoresist.

15. The nano-fabrication method of claim 1, wherein the organic photoresist layer of the step (b) has a thickness of about 20 nm to about 60 nm.

16. The nano-fabrication method of claim 1, wherein the laser beam of the step (c) has a wavelength of about 250 nm to about 500 nm.

17. The nano-fabrication method of claim 1, wherein the step (d) comprises applying an alkali solution to remove the first exposed region of the inorganic resist layer.
